(19) United States
(12) Patent Application Publication
(10) Pub. No.: US 2006/0121254 A1
(43) Pub. Date: Jun. 8, 2006

(54) Patterned substrate, electro-optical device, patterned substrate manufacturing method and electric-optical device manufacturing method

(75) Inventor: Naoyuki Toyoda, Suwa-shi (JP)

Correspondence Address: SHINJYU GLOBAL IP COUNSELORS, LLP, 1233 20TH STREET, NW, SUITE 700, WASHINGTON, DC, 20036-2680, US

(73) Assignee: Seiko Epson Corporation, Shinjuku-ku (JP)

(21) Appl. No.: 11/290,484

(22) Filed: Dec. 1, 2005

(30) Foreign Application Priority Data
Dec. 3, 2004 (JP) 2004-350816

(51) Int. Cl. B41M 5/00; H01L 51/52; H01L 51/56

(52) U.S. Cl. 428/195.1; 427/532; 427/256; 257/88; 257/E51.018; 428/917; 313/506

(57) ABSTRACT

A patterned substrate includes a plurality of patterns formed by drying liquid droplets containing a pattern forming material and a photothermal conversion part configured to convert infrared light into heat provided on an outside perimeter of each of a plurality of pattern forming regions, each pattern forming region being formed to correspond to each of the patterns.

### BACKGROUND

1. Technical Field

The invention relates to a patterned substrate, an electro-optical device, a patterned substrate manufacturing method, and an electric-optical device manufacturing method.

2. Related Art

One known example of a conventional display equipped with light emitting elements is the organic electroluminescent display (organic EL display), which is an electro-optical device equipped with organic electroluminescent elements (organic EL elements). The manufacturing methods for organic EL elements are generally classified according to the material from which the light emitting layer is made. More specifically, when the light emitting layer is made of a low molecular organic material, the light emitting layer is formed by vapor deposition of the low molecular organic material, i.e., a vapor phase process is used. Meanwhile, when a high molecular organic material is used as the material for making the light emitting layer, the light emitting layer is formed using a so called liquid phase process in which the high molecular organic material is dissolved in an organic solvent and the resulting solution is applied in a liquid form and then dried.

Among liquid phase processes, the inkjet method is attracting attention for the following reasons. In the inkjet method, since the solution is ejected as tiny liquid droplets, finer liquid droplets (a more precise liquid pattern) can be formed than with other liquid processes (e.g., spin coating). Furthermore, since the inkjet method deposits the liquid droplets only to the region where the liquid pattern is to be formed (pattern forming region), the amount of high molecular organic material or other constituent material used can be reduced.

However, with the inkjet method, the light emitting layer (pattern) is formed by evaporating (drying) the solvent component of the liquid pattern. Consequently, if the drying conditions vary, unwanted variation will occur in the pattern shape (e.g., the film thickness profile of the organic EL layers) among the patterns within an organic EL element substrate (patterned substrate).

Proposals for suppressing the occurrence of such shape variation among patterns formed using the inkjet method have been around for some time (e.g., JP-UM-A-9-105938). In JP-UM-A-9-105938, the liquid droplets are ejected with the inkjet method, and the amount of time during which the ejected liquid droplets are dried with heat is fixed. As a result, the drying time of each liquid droplet can be made identical and the variation of the shapes of the patterns can be suppressed.

Even if the drying time is identical, the amount of solvent component to be evaporated from the liquid pattern is larger in the sections where the liquid pattern is more densely formed, i.e., in the middle section of the patterned substrate. Consequently, the solvent partial pressure is larger in the middle section of the patterned substrate than in the outer perimeter section of the patterned substrate. As a result, the drying speed is slower in the middle section of the patterned substrate than in the outer perimeter section of the patterned substrate. Thus, the problem of shape variation among the patterns within the patterned substrate still occurs.

### SUMMARY

An advantage of the invention is to provide a patterned substrate, an electro-optical device, a patterned substrate manufacturing method, and an electric-optical device manufacturing method in which the uniformity of the shape of a pattern formed by drying liquid droplets is improved.

A patterned substrate in accordance with a first aspect of the invention is a patterned substrate having an element forming surface, a plurality of patterns formed on the element forming surface by drying liquid droplets containing a pattern forming material, wherein a photothermal conversion part configured to convert infrared light into heat is provided on an outside perimeter of each of a plurality of pattern forming regions, each pattern forming region being formed to correspond to one of the patterns.

With a patterned substrate in accordance with the first aspect of the invention, since a photothermal conversion part is provided on the outside perimeter of each pattern forming region, photothermal conversion parts are concentrated (provided more densely) in the places where the pattern forming regions are formed more densely. Consequently, due to the formation of the photothermal conversion parts, the drying conditions of each droplet can be made more uniform and the uniformity of the shapes of the patterns can be improved.

It is preferable that the photothermal conversion parts contain an infrared absorbing pigment. With this patterned substrate, the heat generated by the infrared absorbing pigment contained in the photothermal conversion parts enables the drying conditions of the liquid droplets to be made uniform and the uniformity of the shapes of the patterns to be improved.

It is preferable that the photothermal conversion parts be provided with partitioning walls configured to hold the liquid droplets in the pattern forming regions. With this patterned substrate, since the liquid droplets are held by the partitioning walls of the photothermal conversion parts, the liquid droplets can be dried by the photothermal conversion parts until the pattern forming material of the held liquid droplets forms the patterns. Thus, the drying conditions of the liquid droplets can be made more uniform and the uniformity of the shapes of the patterns can be improved.

It is preferable that the pattern forming material be a light emitting element forming material and that the patterns be light emitting elements. With this patterned substrate, the drying conditions of the light element forming material can be made uniform and the uniformity of the shape of the light emitting elements can be improved.

It is preferable that the pattern forming material be a color filter forming material and that the patterns be color filters. With this patterned substrate, the drying conditions of the color filter forming material can be made uniform and the uniformity of the shape of the color filters can be improved.

It is preferable that each photothermal conversion part be a light blocking film that shields the outside perimeter of the respective color filter. With this patterned substrate, since the photothermal conversion parts are formed as light blocking films, the uniformity of the shapes of the patterns can be improved even when a separate light blocking film is not formed.

It is preferable that the patterned substrate be a wiring material and that the patterns be wiring patterns. With this patterned substrate, the drying conditions of the wiring forming material can be made uniform and the uniformity of the shape of the wiring patterns can be improved.

An electro-optical device in accordance with another aspect of the invention is an electro-optical device having a plurality of light emitting elements formed by drying liquid droplets containing a light emitting element forming material, wherein a photothermal conversion part configured to convert infrared light into heat is provided on an outside perimeter of each of a plurality of light emitting element forming regions, each light emitting element forming region being formed to correspond to one of the light emitting elements.

With an electro-optical device in accordance with this aspect of the invention, photothermal conversion parts are concentrated (provided more densely) in the places where the light emitting element forming regions are formed more densely because a photothermal conversion part is provided on the outside perimeter of each light emitting element forming region. Consequently, due to the formation of the photothermal conversion parts, the drying conditions of each liquid droplet can be made more uniform and the uniformity of the shapes of the light emitting elements (e.g., the uniformity of the film thickness profile of each light emitting element) can be improved.

It is preferable that the photothermal conversion parts contain an infrared absorbing pigment. With this electro-optical device, the heat generated by the infrared absorbing pigment contained in the photothermal conversion parts enables the drying conditions of the liquid droplets to be made uniform and the uniformity of the shapes of the light emitting elements to be improved.

It is preferable that the photothermal conversion parts be provided with partitioning walls configured to hold the liquid droplets in the light emitting element forming regions. With this electro-optical device, since the liquid droplets are held by the partitioning walls of the photothermal conversion parts, the liquid droplets can be dried by the photothermal conversion parts until the light emitting element forming material of the held liquid droplets forms the light emitting elements. Thus, the drying conditions of the liquid droplets can be made even more uniform and the uniformity of the shapes of the light emitting elements can be improved further.

It is preferable that each photothermal conversion part be a light blocking film that shields the outside perimeter of the respective light emitting element. With this electro-optical device, since the photothermal conversion parts are formed as light blocking films, the uniformity of the shapes of the light emitting elements can be improved even when a separate light blocking film is not formed.

It is preferable that the light emitting elements be electroluminescent elements having a light emitting layer between a transparent electrode and a rear electrode. With this electro-optical device, the uniformity of the shape of the electroluminescent elements can be improved.

It is preferable that the light emitting elements be organic electroluminescent elements in which the light emitting layer is made of an organic material. With this electro-optical device, the uniformity of the shape of the organic electroluminescent elements can be improved.

A patterned substrate manufacturing method in accordance with still another aspect of the invention is a method of manufacturing a patterned substrate having a plurality of patterns formed by drying liquid droplets containing a pattern forming material, comprising: providing a photothermal conversion part configured to convert infrared light into heat on an outside perimeter of each of a plurality of pattern forming regions, each pattern forming region corresponding to one of the patterns; forming the liquid droplets within the pattern forming regions; shining and infrared light on the patterned forming regions; and drying the liquid droplets by heat resulting from the photothermal conversion by the photothermal conversion parts.

With a patterned substrate manufacturing method in accordance with this aspect of the invention, by shining infrared light onto the patterned substrate, the photothermal conversion parts on the perimeters of the pattern forming regions convert the infrared light into heat and the liquid droplets in the pattern forming regions can be dried with the above-mentioned heat. Consequently, due to the formation of the photothermal conversion parts, the uniformity of the shapes of the patterns can be improved.

It is preferable that a liquid droplet ejection device be used to eject the liquid droplets. With this patterned substrate manufacturing method, since the liquid droplets are ejected using a liquid droplet ejection device, the liquid droplets can be ejected exclusively within the photothermal conversion parts and the shapes of the patterns can be made more uniform.

It is preferable that infrared light be shone on the patterned forming regions after liquid droplets are formed in the pattern forming regions. With this patterned substrate manufacturing method, since infrared light is shone onto the substrate after liquid droplets are formed in the pattern forming regions, the amount of time over which each liquid droplet is heated can be made uniform and the uniformity of the shapes of the patterns can be improved.

It is preferable that infrared light is shone on the photothermal conversion parts of the pattern forming regions while liquid droplets are formed in the pattern forming regions. With this patterned substrate manufacturing method, since infrared light is shone onto the photothermal conversion parts of the pattern forming regions while liquid droplets are formed, the amount of time over which each liquid droplet is heated can be made uniform and the uniformity of the shapes of the patterns can be further improved. Furthermore, since heating of the liquid droplets can be completed when the formation of all the liquid droplets is completed, time required for a separate heating step can be reduced and the productivity with which the patterned substrates are manufactured can be improved.

An electro-optical device manufacturing method in accordance with still another aspect of the invention is a method of manufacturing an electro-optical device having a plurality of light emitting elements formed on a light emitting element-encompassing substrate by drying liquid droplets containing a light emitting element forming material. The method includes providing a photothermal conversion part that is configured to convert infrared light into heat on an outside perimeter of each of a plurality of light emitting element forming regions, each light emitting element forming region corresponding to each of the light emitting elements; forming the liquid droplets are formed within the light emitting element forming regions and infrared light is shone on the light emitting element-encompassing substrate; and drying the liquid droplets by heat resulting from the photothermal conversion by the photothermal conversion parts.

With an electro-optical device manufacturing method in accordance with this aspect of the invention, by shining infrared light onto the light emitting element-encompassing substrate, the photothermal conversion parts on the outside perimeters of the light emitting element forming regions convert the infrared light into heat and the liquid droplets in the pattern forming regions can be dried with the above-mentioned heat. Consequently, due to the formation of the photothermal conversion parts, the uniformity of the shapes of the light emitting elements (e.g., the uniformity of the film thickness profile of each light emitting element) can be improved.

It is preferable that a liquid droplet ejection device be used to eject the liquid droplets. With this electro-optical device manufacturing method, since the liquid droplets are ejected using a liquid droplet ejection device, the liquid droplets can be ejected exclusively within the photothermal conversion parts and the shapes of the light emitting elements can be made more uniform.

It is preferable that infrared light be shone on the light emitting element-encompassing substrate after liquid droplets are formed in the light emitting element forming regions. With this electro-optical device manufacturing method, since infrared light is shone onto the substrate after liquid droplets are formed in the light emitting element forming regions, the amount of time over which each liquid droplet is heated can be made uniform and the uniformity of the shapes of the light emitting elements can be improved.

It is preferable that infrared light be shone on the light emitting element-encompassing substrate while liquid droplets are formed in the light emitting element forming regions. With this electro-optical device manufacturing method, since infrared light is shone onto the photothermal conversion parts of the light emitting element forming regions while liquid droplets are formed, the amount of time over which each liquid droplet is heated can be made uniform and the uniformity of the shapes of the light emitting elements can be further improved. Furthermore, since heating of the liquid droplets can be completed when the formation of all the liquid droplets is completed, time required for a separate heating step can be reduced and the productivity with which the electro-optical devices are manufactured can be improved.

### BRIEF DESCRIPTION OF THE DRAWINGS

The invention will be described with reference to the accompanying drawings, wherein like numbers reference like elements.

FIG. 1 is a schematic plan view of an organic EL display embodying the invention.

FIG. 2 is a schematic plan view of the pixels of the same.

FIG. 3 is a schematic cross sectional view of a control element forming region of the same.

FIG. 4 is a schematic cross sectional view of a control element forming region of the same.

FIG. 5 is a schematic cross sectional view of a light emitting element forming region of the same.

FIG. 6 is a flowchart for explaining the process of manufacturing the same electro-optical device.

FIG. 7 is a diagrammatic cross sectional view for explaining the process of manufacturing the same electro-optical device.

FIG. 8 is a diagrammatic cross sectional view for explaining the process of manufacturing the same electro-optical device.

FIG. 9 is a diagrammatic cross sectional view for explaining the process of manufacturing the same electro-optical device.

FIG. 10 is a diagrammatic cross sectional view for explaining a modification of the process of manufacturing the electro-optical device.

FIG. 11 is a schematic cross sectional view of an electro-optical device obtained in accordance with the modification of the embodiment.

### DESCRIPTION OF EXEMPLARY EMBODIMENTS

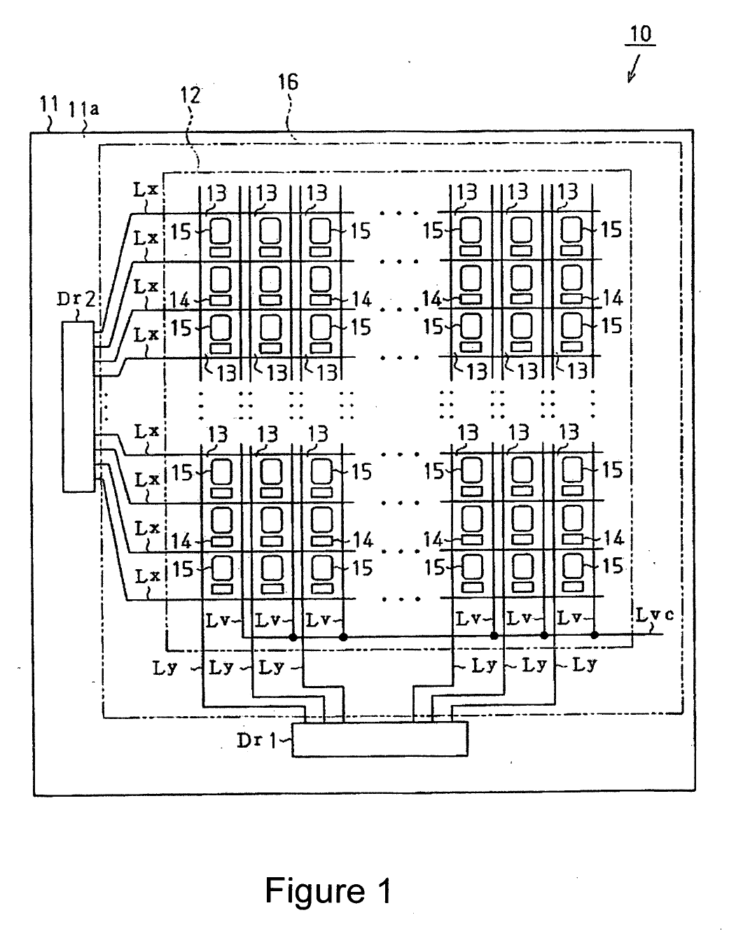

An embodiment of the invention will now be described with reference to FIGS. 1 to 9. FIG. 1 is a schematic plan view of an organic electroluminescent display (organic EL display) which is an example of an electro-optical device.

As shown in FIG. 1, the organic EL display 10 has a transparent substrate 11 as an example of a patterned substrate and a light emitting element-encompassing substrate. The transparent substrate 11 is a non-alkaline glass substrate that is formed into a rectangular shape and has an element forming region 12 formed on the surface thereof (element forming surface 11a). A plurality of data lines Ly that run in the vertical direction (column direction) are formed with a prescribed spacing there-between in the element forming region 12. Each data line Ly is electrically connected to a data drive circuit Dr1 arranged toward the bottom of the transparent substrate 11. The data drive circuit Dr1 is configured to generate a data signal based on display data supplied from an external device (not shown) and output the data signal to the corresponding data lines Ly at a prescribed timing.

A plurality of power supply lines Lv that run in the column direction with a prescribed spacing there-between are also provided in the element forming region 12 along with the data lines Ly. Each power supply line Lv is electrically connected to a common power supply line Lvc formed toward the bottom of the element forming region 12 and a drive power supply generated by a power supply voltage generating circuit (not shown) is supplied to the power supply lines Lv.

A plurality of scan lines Lx that run in a direction perpendicular to the data lines Ly and the power supply lines Lv (i.e., the row direction) are also formed with a prescribed spacing there-between in the element forming region 12. Each scan line Lx is electrically connected to a scan line drive circuit Dr2 formed on the left side of the transparent substrate 11. The scan line drive circuit Dr2 is configured to selectively drive specific scan lines Lx among the plurality of scan lines Lx at specific timings based on a scan control signal supplied from a control circuit (not shown) and output scan signals to the above-mentioned scan lines Lx.

A plurality of pixels 13 are arranged at positions where the data lines Ly and scan lines Lx intersect and connected to the corresponding data line Ly, power supply line Lv, and scan line Lx. The pixels 13 are thus arranged in a matrix form. A control element forming region 14 and a light emitting element forming region 15 are formed inside each pixel 13. The pixels 13 are protected by covering the element forming region 12 with a rectangular sealing substrate 16 (indicated with double-dot chain line in FIG. 1).

Each pixel 13 in this embodiment is a red pixel configured to emit red light, a green pixel configured to emit green light, or a blue pixel configured to emit blue light so that a full color image can be displayed on the back surface (display surface 11b) of the transparent substrate 11.

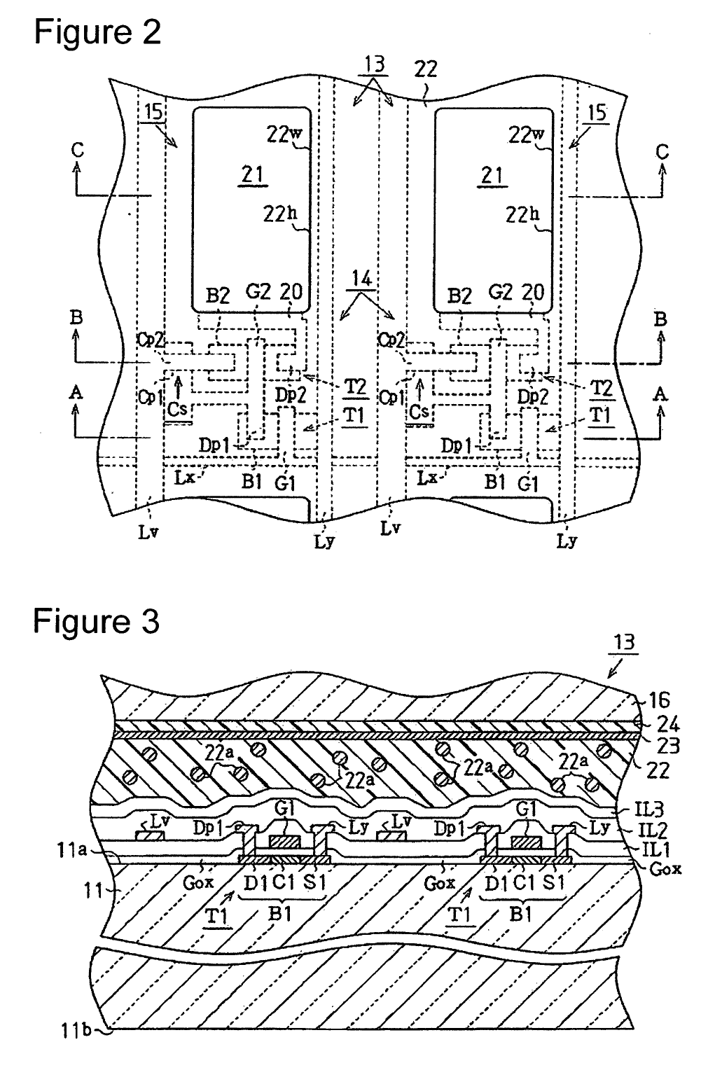

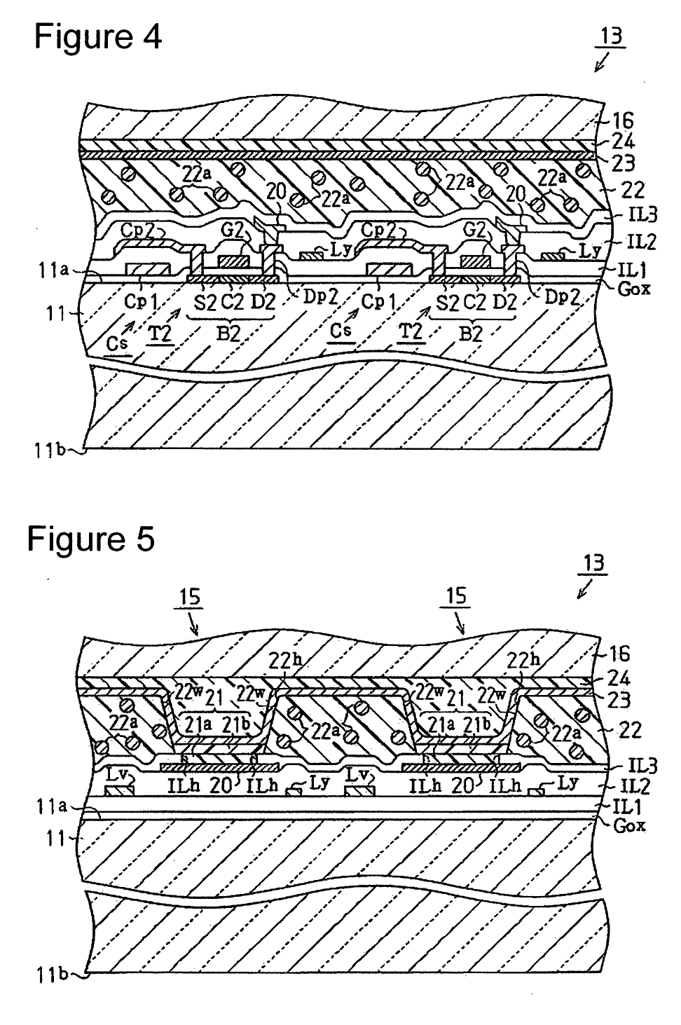

The aforementioned pixels 13 will now be described. FIG. 2 is a schematic plan view showing how the control element forming region 14 and the light emitting element forming region 15 of each pixel 13 are laid out. FIGS. 3 and 4 are schematic cross sectional views of the control element forming regions 14 taken along the single-dotted chain lines A-A and B-B, respectively, of FIG. 2. FIG. 5 is a schematic cross sectional view of the light emitting element forming regions 15 taken along the single-dot chain line C-C of FIG. 2.

First, the control element forming regions 14 will be described. As shown in FIG. 2, a control element forming region 14 is formed toward the bottom of each pixel and each control element forming region 14 includes a first transistor (switching transistor) T1, a second transistor (drive transistor) T2, and a holding capacitor Cs.

As shown in FIG. 3, a first channel film B1 is provided in the lowermost layer of the switching transistor T1. The first channel film B1 is an island-like p-type polysilicon film formed on the element forming surface 11a and a first channel region C1 is formed in a middle position of the first channel film B1. Activated n-type regions (first source region S1 and first drain region D1) are formed on the left and right sides of the first channel region C1. Thus, the switching transistor T1 is a so-called polysilicon TFT.

A gate insulating film Gox and a first gate electrode G1 are formed over the first channel region C1 in order as listed in the direction moving away from element forming surface 11a. The gate insulating film Gox is an insulating film made of silicon oxide or other material that is transmissive to light and is deposited over the first channel region C1 and on substantially the entire surface of the element forming surface 11a. The first gate electrode G1 is a low-resistance metal film made of tantalum, aluminum, or the like and is formed in a position facing toward (aligned with) the first channel region C1. As shown in FIG. 2, the first gate electrode G1 is electrically connected to scan line Lx. As shown in FIG. 3, the first gate electrode G1 is electrically insulated by a first interlayer insulating film IL1 that is deposited over the gate insulating film Gox.

When the scan line drive circuit Dr2 sends a scan signal to the first gate electrode G1 of a pixel through a scan line Lx, the switching transistor T1 turns on (enters an ON state) based on the scan signal.

A data line Ly passes through the first interlayer insulating film IL1 and the gate insulating film Gox and connects electrically to the first source region S1. A first drain electrode Dp1 passes through the first interlayer insulating film IL1 and the gate insulating film Gox and connects electrically to the first drain region D1. The data line Ly and the first drain electrode Dp1 are electrically insulated by a second interlayer insulating film IL2 deposited over the first interlayer insulating film IL1, as shown in FIG. 3.

When the scan line drive circuit Dr2 sequentially selects one scan line Lx at a time by executing line sequential scanning, the switching transistors T1 of the pixels 13 connected to each selected scan line Lx sequentially enter the ON state and remain ON only so long as the respective scan line Lx is selected. When the switching transistor T1 of a particular pixel enters the ON state, the data signal from the data line drive circuit Dr1 is outputted to the first drain electrode Dp1 through the data line Ly and the switching transistor T1 (channel film B1).

As shown in FIG. 4, the drive transistor T2 is a polysilicon TFT provided with a channel film B2 having a second channel region C2, a second source region S2, and a second drain region D2. A second gate electrode G2 is formed over the second channel film B2 with the gate insulating film Gox disposed there-between. The second gate G2 is a low-resistance metal film made of tantalum, aluminum, or the like and, as shown in FIG. 2, is electrically connected to the first drain electrode Dp1 of the switching transistor T1 and a lower electrode Cp1 of the holding capacitor Cs. As shown in FIG. 4, the second gate electrode G2 and the lower electrode Cp1 are electrically insulated by the first interlayer insulating film IL1 deposited over the gate insulating film Gox.

The second source region S2 is electrically connected to an upper electrode Cp2 of the holding capacitor Cs, the upper electrode Cp2 being so arranged as to pass through the first interlayer insulating film IL1. As shown in FIG. 2, the upper electrode Cp2 is electrically connected to the corresponding power supply line Lv. Thus, as shown in FIGS. 2 and 4, the holding capacitor Cs uses the first interlayer film IL1 as a capacitor film and is connected between the second source region S2 and the second gate electrode G2 of the drive transistor T2. The second drain region D2 is electrically connected to a second drain electrode Dp2 that passes through the first interlayer film IL1. The second drain electrode Dp2 and the upper electrode Cp2 are electrically insulated by the second interlayer insulating film IL2 deposited over of the first interlayer insulating film IL1.

When the data signal from the data line drive circuit Dr1 is outputted to the first drain region D1 through the switching transistor T1, the holding capacitor Cs stores an electric charge corresponding to the data signal. Then, when the switching transistor T1 turns off (enters the OFF state), a drive current corresponding to the electric charge stored in the holding capacitor Cs is outputted to the second drain region D2 through the drive transistor T2 (channel film B2).

The light emitting element regions 15 will now be described. As shown in FIG. 2, a rectangular light emitting element forming region is formed toward the bottom of each pixel 13. As shown in FIG. 5, in a light emitting element forming region 15, an anode 20 is formed over the second interlayer insulating film IL2. The anode 20 is a transparent electrode and constitutes the lowermost layer of the light emitting element forming region 15.

The anode 20 is a transparent conductive film that is transmissive to light. As shown in FIG. 4, one end of the anode 20 passes through the second interlayer film IL2 and connects electrically to the second drain region D2.

A third interlayer insulating film IL3 made of silicon oxide or other material is deposited over the anode 20 and serves to insulate the anodes 20 of the plurality of pixels 13 from each other. Rectangular through holes ILh that open upward from positions at the approximate middle of each anode 20 are provided in the third interlayer insulating film IL3. A photothermal conversion layer 22 as an example of a photothermal conversion part is formed over the third interlayer insulating film IL3.

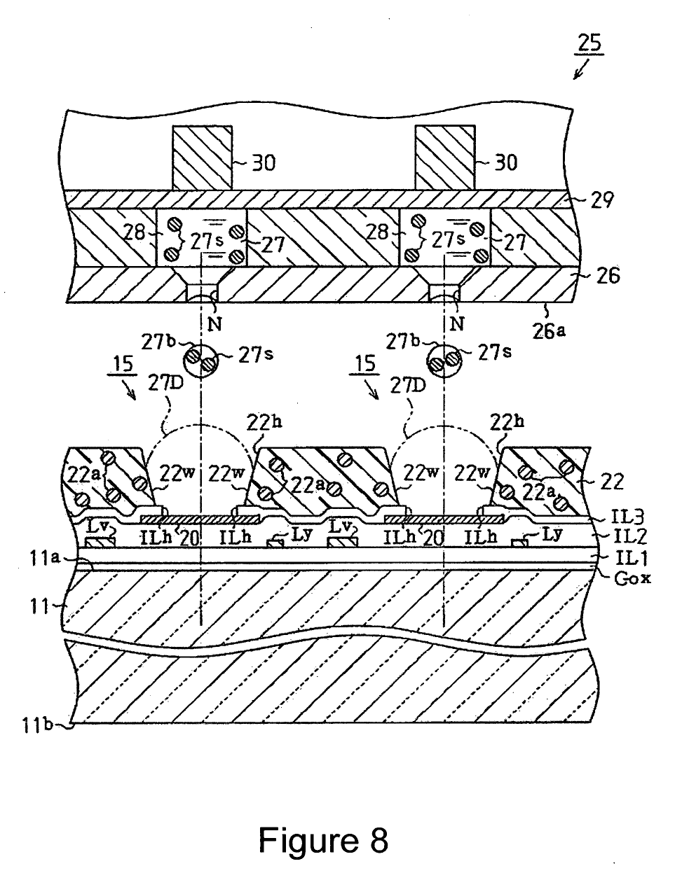

The photothermal conversion layer 22 is made of a photosensitive polyimide or other resin that repels the hole transport layer forming material solution 27 (see FIG. 8) described later and contains an infrared absorbing material 22a (an example of an infrared absorbing pigment) that converts infrared light (wavelengths from approximately 760 to 1300 nm) into heat. The photothermal conversion layer 22 contains carbon black, graphite, or other material that blocks visible light. Thus, the photothermal conversion layer 22 is a light blocking film that blocks visible light and absorbs infrared light, the absorption of infrared light causing it to emit heat.

In this embodiment, the infrared absorbing material 22a is a material or a combination of materials selected from among, for example, azulene based pigment, cyanine dye, indolenine based pigment, polymethene based pigment, immonium based pigment, anthracene based pigment, squarilium based pigment, phthalocyanine based pigment, naphthalocyanine based pigment, a naphthoquinone based pigment, and triarylmethane based pigment. The infrared absorbing material 22a might also be selected from among, for example, azocobalt complex based, dithiol nickel complex based, and diimmonium based compounds. The infrared absorbing material 22a can also be selected from thiol nickel salt, anthraquinone based dye, and nitroso compound or a metal complex salt thereof. Moreover, the carbon black or graphite used for the purpose of blocking visible light is also effective at absorbing infrared light and thus can be used dually as the infrared absorbing material 22a.

A tapered holding hole 22h that opens upward in a tapered shape at a position aligned with the through hole ILh is formed in the photothermal conversion layer 22. Each holding hole 22h is formed to such a size that it can hold a liquid droplet 27D (described later, see FIG. 8) in the corresponding light emitting element forming region.

A heating wall 22w as an example of a partition wall is formed by the inside surface of each through hole 22h. The heating wall 22w (holding hole 22h) and the through hole ILh surround the outer perimeter of each light emitting element forming region 15.

A hole transport layer 21a made of a hole transport layer forming material 27s (see FIG. 8) that exemplifies a pattern forming material constituting a light emitting element forming material is formed over the anode 20 within each light emitting element forming region 15. A light emitting layer 21b made of a light emitting layer forming material that exemplifies a pattern forming material constituting a light emitting element forming material is formed over the hole transport layer 21a.

The hole transport layer 21a and the light emitting layer 21b constitute an organic electroluminescent layer (organic EL layer) 21. Thus, a heating wall 22w is formed around the perimeter of each organic EL layer 21 and the heating walls 22w are formed more densely in the vicinity of the middle of the transparent substrate 11, where the organic EL layers 21 are formed more densely.

In this embodiment, the light emitting layers 21b are each made of a light emitting layer forming material of the corresponding color (a red light emitting layer forming material that emits red light, a green light emitting layer forming material that emits green light, or a blue light emitting layer forming material that emits blue light).

A cathode 23 that exemplifies a rear electrode and comprises a light reflective metal film made of aluminum or other metal is formed over the organic EL layer 21 and the photothermal conversion layer 22 (heating walls 22w). The cathode 23 is formed to cover the entire surface of the element forming surface 11a such that the pixels 13 all use a common cathode and a common electric potential can be supplied to each light emitting element forming region 15.

In short, an organic electroluminescent element (organic EL element) is formed by each anode 20 and organic EL layer 21 in combination with the cathode 23.

When a drive current corresponding to the data signal is supplied to an anode 20 through the second drain region D2, the organic EL layer emits light at a brightness corresponding to the drive current. When this occurs, the portion of the light that is emitted toward the cathode 23 from the organic EL layer 21 (upward in FIG. 4) is reflected by the cathode 23. Consequently, most of the light emitted from the organic EL layer 21 passes through the anode 20, the second interlayer insulating film IL2, the first interlayer insulating film IL1, the gate insulating film Gox, the element forming surface 11a, and the transparent substrate 11 and is discharged outward from the rear side (display surface 11b) of the transparent substrate 11. Thus, an image based on the data signal is displayed on the display surface 11b of the organic EL display 10.

An adhesive layer 24 made of an epoxy resin or the like is formed over the cathode 23 and the sealing substrate 16 is attached to the adhesive layer 24 so as to cover the element forming region 12. The sealing substrate 16 is a non-alkaline glass substrate and serves to prevent oxidation of the pixels 13 and the wiring conductor lines Lx, Ly, Lv.

Method of Manufacturing the Organic EL Display 10

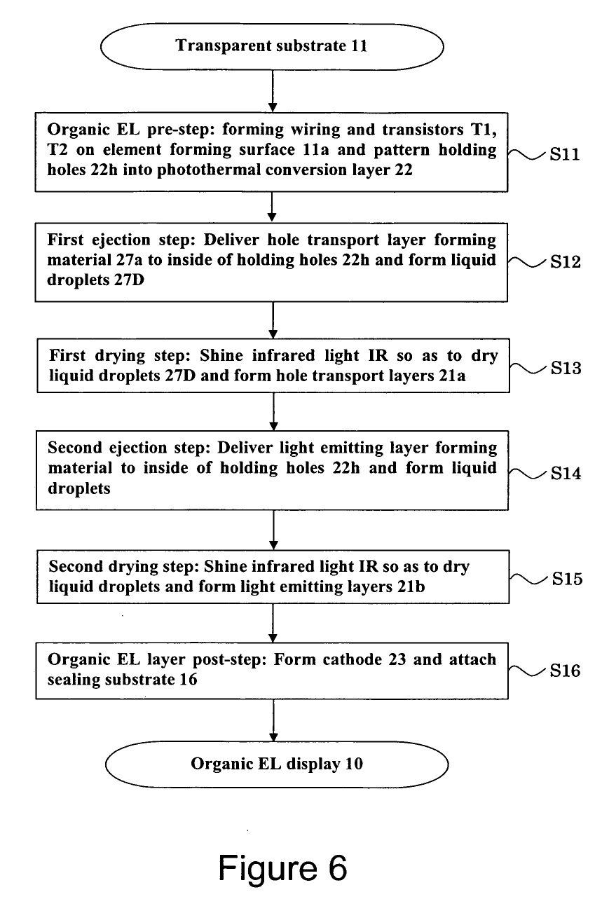

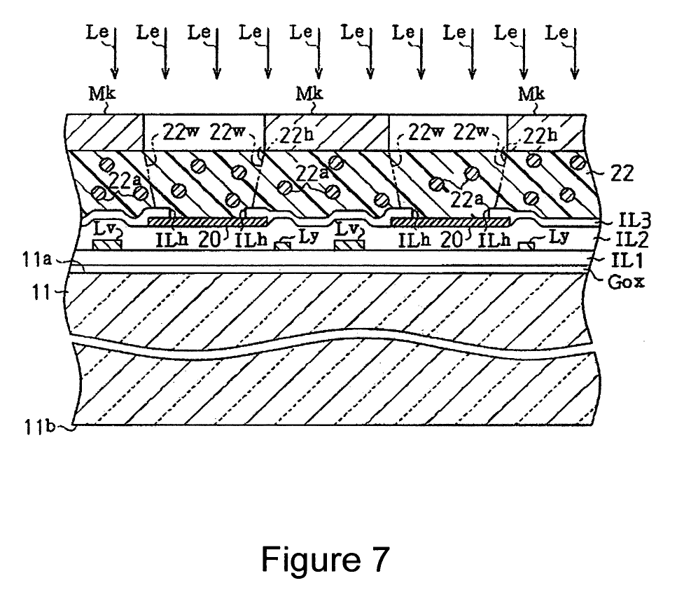

A method of manufacturing the organic EL display 10 will now be described. FIG. 6 is a flowchart explaining the method of manufacturing the organic EL display 10 and FIGS. 7 to 9 are diagrammatic cross sectional views for explaining the same.

As shown in FIG. 6, first an organic EL layer pre-step (step 11) is executed in which the wiring conductor lines Lx, Ly, Lv, and Lvc and the transistors T1, T2 are formed on the element forming surface 11a of the transparent substrate 11 and holding holes 22h are patterned into the photothermal conversion layer 22.

More specifically, in the organic EL layer pre-step, a polysilicon film crystallized by an excimer laser or the like is formed over the entire surface of the element forming surface 11a and the polysilicon film is patterned to form the channel films B1, B2. Next, a gate insulating film Gox made of silicon oxide or other material is formed over the entire surface of the channel films B1, B2 and the element forming surface 11a and a low-resistance metal film made of tantalum or other metal is deposited over the entire surface of the gate insulating film Gox. The low-resistance metal film is then patterned to form the gate electrodes G1, G2, the lower electrode Cp1 of the holding capacitor Cs, and the scan lines Lx.

After the gate electrodes G1, G2 are formed, regions doped with an n-type impurity are formed in each of the channel films B1, B2 using an ion doping method that employs the gate electrodes G1, G2 as masks. As a result, the channel regions C1, C2, source regions S1, S2, and the drain regions D1, D2 are formed. After a source region S1, S2 and a drain region D1, D2 have been formed in each of the channel films B1, B2, a first interlayer insulating film IL1 made of silicon oxide or other material is deposited over the entire surfaces of the gate electrodes G1, G2, the lower electrode Cp1, the scan lines Lx, and the gate insulating film Gox.

Once the first interlayer insulating film IL1 is deposited, pairs of contact holes are patterned through the first interlayer insulating film IL1 at positions corresponding to the source region S1, S2 and drain region D1, D2 of each channel film. Next, a film of aluminum or other metal is deposited over the entire surface of the first interlayer insulating film IL1 and inside the contact holes. The, metal film is then patterned to form the data lines Ly corresponding to each of the source regions S1, S2 and the upper electrode Cp2 of each holding capacitor Cs. Simultaneously, the drain electrodes Dp1, Dp2 corresponding to each of the drain regions D1, D2 are formed. Then, a second interlayer insulating film IL2 made of silicon oxide or other material is formed over the entire surfaces of the data lines Ly, the upper electrodes Cp2, the drain regions D1, D2, and the first interlayer insulating film IL1. As a result, the switching transistors T1 and the drive transistors T2 are formed.

After the second interlayer insulating film IL2 is deposited, via holes are formed in the second interlayer insulating film IL2 at positions corresponding to the second drain regions D2. Then, a transparent conductive film made of ITO or other material that is transmissive to light is deposited over the entire surface of the second interlayer insulting film IL2 and inside the via holes and the transparent conductive film is patterned to form anodes 20 that connect to the second drain regions D2. After the anodes 20 are formed, a third interlayer insulating film IL3 made of silicon oxide or other material is deposited over the entire surfaces of the anodes 20 and the second interlayer insulating film IL2. After the third interlayer insulating film IL3, a through hole ILh is formed through the third interlayer insulating film IL3 above each anode 20.

After the through holes ILh are formed, a photothermal conversion layer 22 made of a photosensitive polyimide resin containing an infrared absorbing material 22a is formed over the entire surface of the third interlayer insulating film IL3 and inside the through holes ILh using a paint application method. In this embodiment, the photothermal conversion layer 22 is made of a so-called positive photosensitive material that becomes soluble in a developer liquid made of an alkaline solution or the like when exposed to an exposure light Le of a prescribed wavelength (see FIG. 7), only the exposed portion of the photosensitive material becoming soluble in the above-mentioned developer liquid.

Next, as shown in FIG. 7, the photothermal conversion layer 22 is exposed to exposure light Le of a prescribed wavelength through a photo mask Mk having openings in positions corresponding to the through holes ILh and then the exposed photothermal conversion layer 22 is developed. As a result, holding holes 22h whose internal surfaces constitute heating walls 22w are patterned into the photothermal conversion layer 22. In summary, after the wiring conductor lines Lx, Ly, Lv, Lvc and the transistors T1, T2 are formed on the element forming surface 11a, the organic EL layer pre-step ends with the completion of the patterning of the holding holes 22h.

As shown in FIG. 6, after the organic EL layer pre-step is completed, a first ejection step (step S12) is executed in order to form liquid droplets 27D containing a hole transport layer forming material 27s inside the holding holes 22h.

In this embodiment, the hole transport layer forming material 27s is made of a low molecular compound of benzidine derivative, stearylamine derivative, triphenylmethane derivative, triphenylamine derivative, and hydrazone derivative or a high molecular compound of which a portion includes these structures. The hole transport layer forming material 27s can also be made of, for example, a high molecular compound of polyaniline, polythiophene, polyvinylcarbozol, α-naphthyl phenyl diamine, and a mixture of poly(3,4 ethylenedioxythiophene) and polystyrene sulfonic acid (PEDOT/PSS) (Baytron P, trademark of Bayer AG). Also, solvents for dissolving the hole transport layer forming material include, for example, N-methyl pyrrolidone and 1,3-dimethyl-2-imidazolidinone.

FIG. 8 is a diagrammatic view illustrating the first ejection step.

First, the constituent features of a liquid droplet ejection device used to eject the hole transport layer forming material solution 27 in which the hole transport layer forming material 27s is dissolved will be described.

As shown in FIG. 8, the liquid droplet ejection device has a liquid droplet ejection head 25 provided with a nozzle plate 26. Multiple upward facing nozzles N configured to eject the solution (hole transport layer forming material solution 27) in which the hole transport layer forming material 27s is dissolved are formed in the bottom face (nozzle forming face 26a) of the nozzle plate 26. Above each nozzle N is a supply chamber 28 capable of supplying the hole transport layer forming material solution 27 to the inside of the nozzle N, the supply chambers 28 being in communication with a solution holding tank (not shown). A vibrating plate 29 is arranged above the supply chambers 28 and is configured to vibrate reciprocally in the up and down direction so as to expand and contract the internal volumes of the supply chambers 28. Piezoelectric elements 30 are arranged above the vibrating plate 29 at positions corresponding to the supply chambers 28 and are configured to elongate and contract in the up and down direction so as to vibrate the vibrating plate 29.

A transparent substrate 11 is carried to the liquid droplet ejection device and positioned such that the element forming surface 11a is parallel to the nozzle forming surface 26a and the center positions of the holding holes 22h are aligned directly below the nozzles N, as shown in FIG. 8.

When a drive signal for ejecting the liquid droplets is received by the liquid droplet ejection head, the piezoelectric elements 30 elongate and contract based on the drive signal and cause the volumes of the supply chambers 28 to expand and contract. When the volumes of the supply chambers 28 contract, a quantity of hole transport layer forming material solution 27 corresponding to the reduction in volume is discharged from each nozzle N as a tiny liquid droplet 27b. The discharged tiny liquid droplets 27b are each deposited on the anode 20 inside the respective holding hole 22h. Afterwards when the volumes of the supply chambers 28 expand, a quantity of hole transport layer forming material solution 27 corresponding to the increase in volume is supplied to each supply chamber 28 from the holding tank (not shown). Thus, the liquid droplet ejection head 25 discharges a prescribed volume of hole transport layer forming material solution 27 toward the holding holes 22h by means of this expansion and contraction of the supply chambers 28.

The plurality of tiny liquid droplets 27b shot into the holding holes 22h form a liquid droplet 27D whose surface assumes a semi-spherical shape (indicated by a double-dot chain line in FIG. 8) due to surface tension and the liquid repellency of the heating wall 22w. The liquid droplet ejection head 25 discharges a quantity of tiny liquid droplets Ds from each nozzle N that is sufficient to form a film of hole transport layer forming material 27s having a prescribed thickness inside each through hole ILh when the solvent component of the liquid droplet 27D evaporates. Thus, the first ejection step ends with the formation of the liquid droplets 27D inside the holding holes 22h.

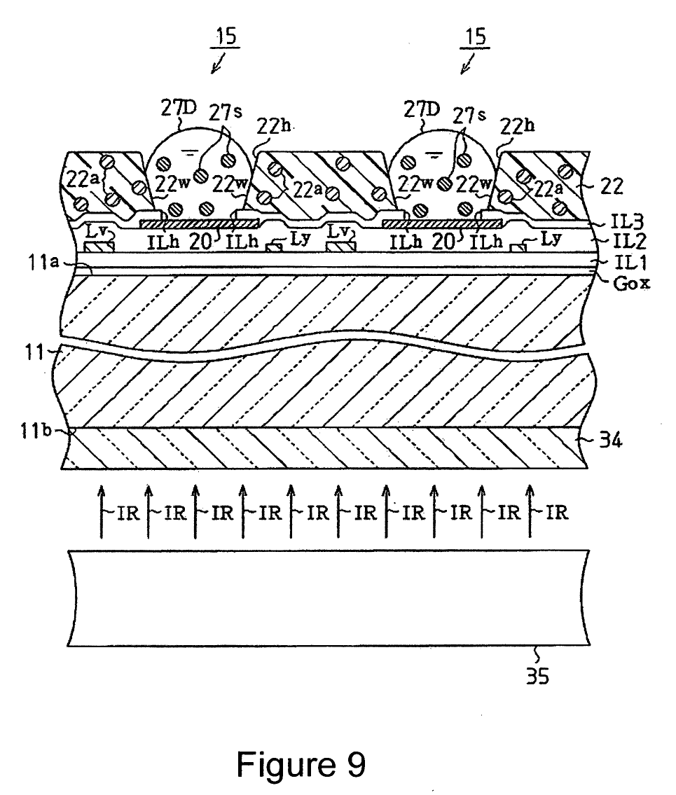

As shown in FIG. 6, after the first ejection step ends, a first drying step (step S13) is executed to dry and cure (harden) the liquid droplets 27D. More specifically, as shown in FIG. 9, the transparent substrate 11 is placed on a substrate stage 34 that is transmissive to infrared light and the display surface 11b of the transparent substrate 11 is arranged in such a position that it faces toward an infrared lamp 35. The infrared light IR emitted from the infrared lamp 35 shines on the entire surface of the display surface 11b of the transparent substrate 11.

When the infrared light shines on the display surface 11b, the infrared absorbing material 22a of the photothermal conversion layer 22 absorbs the infrared light and the photothermal conversion layer 22 emits an amount of heat corresponding to the absorbed infrared light. In short, the heating walls 22w emit heat and heat the liquid droplets 27D. As a result, the solvent components of the liquid droplets 27D evaporate and the hole transport layer forming material 27s cures to form the hole transport layer 21a.

In the vicinity of the middle portion of the transparent substrate 11, the partial pressure of the solvent component is higher in accordance with the denser population of liquid droplets 27D. Meanwhile, in the vicinity of the above-mentioned middle portion, the ambient temperature above the transparent substrate 11 becomes higher in accordance with the denser population of heating walls 22w. In other words, the lower drying speed of the liquid droplets 27D that occurs in the vicinity of the middle portion of the transparent substrate 11 due to the increased partial pressure of the solution can be compensated for by the higher density of heating walls 22w and the same drying speed can be achieved in the above-mentioned middle portion as on the outer perimeter portions of the transparent substrate 11.

Therefore, the liquid droplets 27D can be dried in a manner independent of the partial pressure distribution of the solvent component and the shapes of the hole transport layer forming material 27s (hole transport layers) cured inside the holding holes 22h (through holes ILh) can be made uniform within the element forming surface 11a. Thus, the first drying step ends with the drying and curing of the liquid droplets 27D.

As shown in FIG. 6, after the first dying step is completed, a second ejection step (step S14) is executed in order to form a liquid droplet containing a light emitting layer forming material of the corresponding color inside each holding hole 22h. More specifically, similarly to the first ejection step, a light emitting layer forming material solution comprising dissolved light emitting layer forming material of the respective color is discharged from each nozzle N into the corresponding holding hole 22h and the solution forms a liquid droplet whose surface has a semi-spherical shape inside each holding hole 22h.

In this embodiment, the red light emitting material can be, for example, a high molecular compound having an alkyl or alkoxy substituent in the benzene ring of a polyvinylene styrene derivative or a high molecular compound having a cyano group in the vinylene group of a polyvinylene styrene derivative. The green light emitting material can be, for example, a polyvinylene styrene derivative having an alkyl, alkoxy, or aryl substituent introduced into the benzene ring thereof. The blue light emitting material can be, for example, a polyfluorene derivative (a copolymer of dialkylfluorene and anthracene or a copolymer of dialkylfluorene and thiophene.

Examples of solvents in which these colored light emitting layer forming materials dissolve include toluene, xylene, cyclohexylbenzene, dihydrobenzofuran, trimethylbenzene, and tetramethylbezene.

As shown in FIG. 6, after the second ejection step ends, a second drying step (step S15) is executed to dry and cure (harden) the liquid droplets of light emitting layer forming material. More specifically, similarly to the hole transport layer forming steps, infrared light emitted from an infrared lamp 35 is shone onto the entire display surface 11b of the transparent substrate 11 and the light emitting layer forming material is thereby cured, forming a light emitting layer 21b. In this way, similarly to the hole transport layer 21a, the light emitting layer 21b can be formed in such a manner as to have a uniform film thickness distribution with respect to the element forming surface 11a and, thus, the organic EL layer 21 comprising the hole transport layer 21a and the light emitting layer 21b can be formed in such a manner as to have a uniform film thickness distribution on the element forming surface 11a.

As shown in FIG. 6, after the second drying step ends, an organic EL layer post-step (step 16) is executed in which a cathode 23 is formed over the organic EL layer 21 and the photothermal conversion layer 22 and the pixels 13 are sealed. More specifically, a cathode 23 comprising a film of aluminum or other metal is deposited on the entire upper surface of the organic EL layer 21 and the photothermal conversion layer 22, thereby forming organic EL elements each comprising an anode 20, an organic EL layer 21, and a cathode 23. Once the organic EL elements are completed, an epoxy resin or the like is applied over the entire upper surface of the cathode 23 (pixels 13) to form an adhesive layer 24 and a sealing substrate 16 is attached to the transparent substrate 16 over the adhesive layer 24.

Thus, with this manufacturing method, an organic EL display 10 whose organic EL layer 21 has a uniform film thickness distribution on the element forming surface 11a can be manufactured.

The effects of an embodiment having the constituent features described heretofore will now be explained.

(1) With this embodiment, a photothermal conversion layer 22 containing an infrared absorbing material 22a is formed on the perimeter of a light emitting element forming region 15 and holding holes 22h are formed in the photothermal conversion layer 22. Also, liquid droplets 27D made of a hole transport layer forming material solution 27 are formed inside the holding holes 22h (step S1 2) and the liquid droplets 27D are dried by shining infrared light IR on the entire surface of the display surface 11b (step S 13). After the liquid droplets 27D have been dried and the hole transport layer 21a has been formed, similarly to the method of forming the hole transport layer 21a, liquid droplets of a light emitting layer forming material solution are formed inside the same holding holes 22h and the liquid droplets are dried by shining infrared light IR and heating the photothermal conversion layer 22.

In other words, the lower drying speed of the liquid droplets 27D that occurs in the vicinity of the middle portion of the transparent substrate 11 (element forming surface 11a) due to the increased partial pressure of the solution can be compensated for by the higher density of photothermal conversion layers 22 (heating walls 22w) and the same drying speed can be achieved in the above-mentioned middle portion as on the outer perimeter portions of the transparent substrate 11. As a result, the uniformity of the shapes of the organic EL layers 21 with respect to the element forming surface 1 a (e.g., the uniformity of the film thickness profiles of the hole transport layers 21a and the uniformity of the film thickness profiles of the light emitting layers 21b) can be improved.

(2) With this embodiment, the photothermal conversion layer 22 is provided with holding holes 22h for holding the liquid droplets 27D. Thus, the liquid droplets 27D can be heated by the heating walls 22w until the hole transport layer forming material 27s contained in the liquid droplets 27D forms the hole transport layer 21a. As a result, the uniformity of the shapes of the organic EL layers 21 with respect to the element forming surface 11a can be reliably improved.

(3) With this embodiment, the photothermal conversion layer 22 is made to contain carbon black or other material that blocks visible light so that the photothermal conversion layer 22 blocks visible light. As a result, a step for forming light blocking films to block light between organic EL layers can be eliminated and the uniformity of the shapes of the organic EL layers 21 can be improved.

(4) With this embodiment, liquid droplets 27D are formed in all of the light emitting element forming regions 15 on the element forming surface 11a and, afterwards, infrared light IR emitted from an infrared lamp 35 is shone onto the entire display surface 11b. As a result, the amount of time during which each liquid droplet 27D is dried by the photothermal conversion layer 22 can be made uniform and the uniformity of the shapes of the organic EL layers 21 can be further improved.

(5) In this embodiment, the liquid droplets 27D are formed by a liquid discharged from a liquid droplet ejection device. Thus, the hole transport layer forming material solution 27 and the light emitting layer forming material solution can be ejected exclusively to the insides of the holding holes 22h and the sizes of the individual liquid droplets 27D can be made uniform. As a result, the uniformity of the shapes of the organic EL layers 21 can be further improved.

It is also acceptable to modify the embodiment described above in the following ways.

In the previously described embodiment, the infrared light IR emitted from the infrared lamp 35 is shone onto the display surface 11b of the transparent substrate 11. However, the invention is not limited to this shining method. It is also acceptable to shine the infrared light IR onto the element forming surface 11a of the transparent substrate 11. Any shining method is acceptable as long as the infrared light IR reaches the photothermal conversion layer 22.

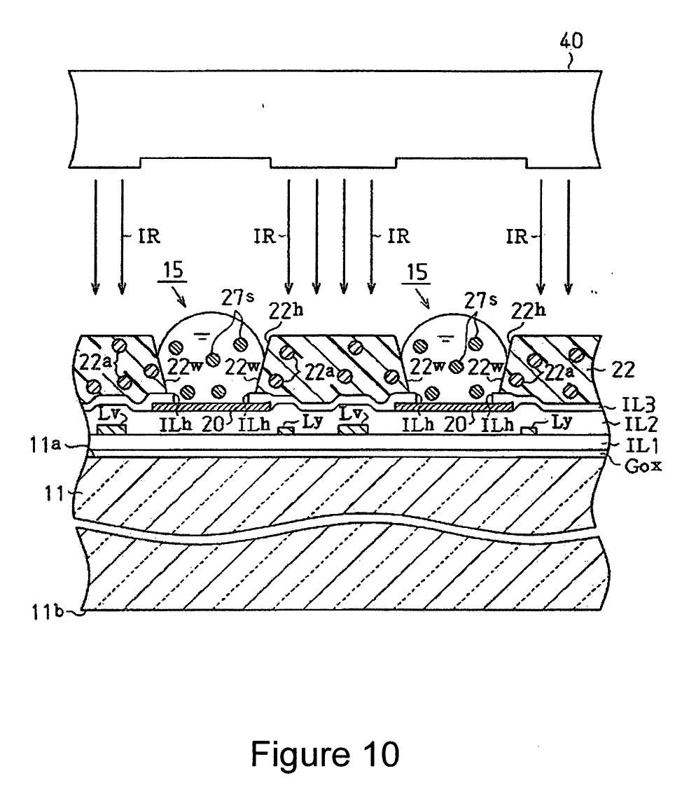

In the previously described embodiment, the source of the infrared light IR is an infrared lamp 35. However, it is also acceptable to change the infrared light source to an infrared laser 40 as shown in FIG. 10. By using an infrared laser, the infrared light IR can be shone onto the photothermal conversion layer 22 only and the uniformity of the shapes of the patterns can be improved even further.

Furthermore, it is also acceptable to arrange the infrared laser 40 nearby the liquid droplet ejection head 25 and heat the photothermal conversion layer 22 arranged around the perimeter of each liquid droplet 27D with the infrared laser light while the liquid droplet 27D is being formed. By shining the infrared laser light while the liquid droplets 27D are being formed, the drying time of each liquid droplet 27D can be made more uniform and the shapes of the organic EL layers 21 with respect to the element forming surface 11A can be made even more uniform. When an infrared laser is used, it is preferable for the infrared absorbing material 22a to be made of such a laser light absorbing material as cyanine pigment, phthalocyanine pigment, naphthalocyanine pigment, anthraquinone pigment, pyrilium pigment or other pigment, or carbon black, graphite or other black material.

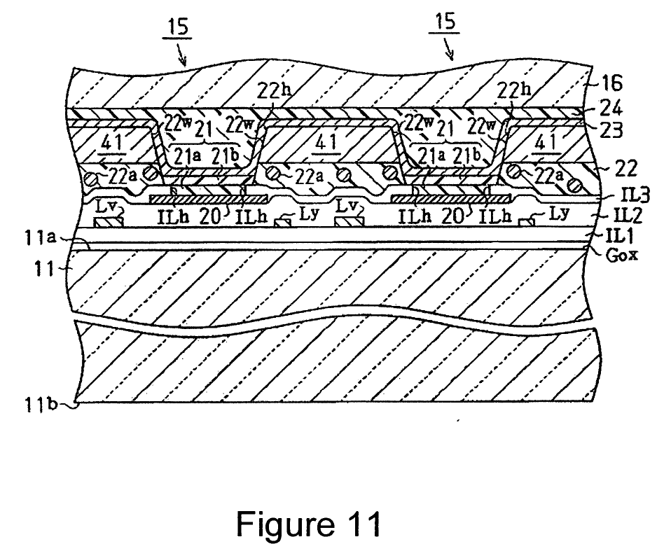

In the previously described embodiment, holding holes 22h are formed in the photothermal conversion layer 22 and the liquid droplets 27D are held inside the holding holes 22h. However, the invention is not limited to this approach. It is also acceptable to form partition walls 41 for holding the liquid droplets 27D on top of the photothermal conversion layer 22 as shown in FIG. 11 and hold the liquid droplets 27D with the partition walls 41.

Although in the previously described embodiment the infrared absorbing material 22a is made of any of various organic materials, the invention is not limited to organic materials and it is also acceptable to use such inorganic materials as chromium or an oxide or sulfide of aluminum. So long as the material absorbs infrared light and converts the light into heat, it does not mater if the material is organic or inorganic.

Although in the previously described embodiment the hole transport layer forming material 27s and the light emitting layer forming material are organic high molecular materials, the invention is not limited to using such materials and the invention can be acceptably worked using well-known low molecular materials. It is also acceptable to provide an electron injection layer comprising, for example, a laminated film of lithium fluoride and calcium over the light emitting layer 21b.

Although in the previously described embodiment a switching transistor T1 and a drive transistor T2 are provided in each control element forming region 14, the invention is not limited to such elements and the invention can be acceptably worked using any desired arrangement of control elements. For example, element arrangements having one transistor, multiple transistors, or multiple capacitors are acceptable.

In the previously described embodiment, the transparent substrate 11 is placed on a substrate stage 34 and infrared light is shone onto the transparent substrate 11. In addition to this, it is also acceptable to provide a temperature sensor on the substrate stage 34 to detect the temperature of the transparent substrate 11 and control the emission intensity of the infrared light based on the temperature detected by the temperature sensor. In other words, it is acceptable to configure the drying steps such that the temperature of the transparent substrate 11 is maintained at a prescribed temperature (e.g., an upper limit temperature for drying the liquid droplets) by controlling the emission intensity of the infrared light.

In the previously described embodiment, the organic EL layer 21 is formed using an inkjet method. The invention is not limited to using an inkjet method to form the organic EL layer 21. For example, it is also acceptable to use a spin coat method or any other method whereby the organic EL layer 21 is formed by drying and curing a liquid.

Although in the previously described embodiment the tiny liquid droplets 27b are ejected using piezoelectric elements 30, the invention is not limited to such an ejection method. For example, it is also acceptable to provide a resistance heating element in the supply chamber 28 and eject the tiny liquid droplets 27b by heating the resistance heating element such that bubbles form and tiny liquid droplets are discharged when the bubbles break.

In the previously described embodiment, the photothermal conversion layers 22 are formed around the perimeters of light emitting element forming regions 15 and utilized to dry and cure a hole transport layer forming material solution 27 and a light emitting layer forming material solution. However, the invention is not limited to substrates patterned with light emitting elements. For example, the invention can also be worked by forming photothermal conversion layers 22 on a patterned substrate provided with color filters of one or more colors (i.e., a color filter substrate). That is, it is acceptable for the pattern to be color filters of one or more colors instead of light emitting elements and for the photothermal conversion layers 22 to be formed around the perimeters of color filter forming regions (pattern forming regions) in which the color filters are formed instead of around light emitting element forming regions. Thus, the photothermal conversion layers 22 can be used to dry and cure a color filter forming material solution that forms color filters. As a result, the uniformity of the shapes of the color filters of various colors formed on a color filter substrate can be improved.

Furthermore, it is also acceptable to form photothermal conversion layers 22 on a patterned substrate (wiring substrate) provided with wiring patterns. That is, it is acceptable for the pattern to be wiring patterns and for the photothermal conversion layer 22 to be formed around the perimeters of wiring pattern forming regions in which the wiring patterns are formed. Thus, the photothermal conversion layers 22 can be used to dry and cure a wiring forming material dispersion liquid that forms wiring patterns. As a result, the uniformity of the shapes of the wiring patterns formed on a wiring substrate can be improved.

Although in the previously described embodiment the electro-optical device is an organic EL display 10, the invention is not limited to an organic EL display. For example, the invention can be applied to a backlight mounted to a liquid crystal panel or to a field effect display (FED, SED, or the like) that is provided with a flat planar electron emitting element and utilizes light emitted from a fluorescent substance exposed to electrons emitted from the above-mentioned electron emitting element.

This application claims priority to Japanese Patent Application No. 2004-350816. The entire disclosure of Japanese Patent Application No. 2004-350816 is hereby incorporated herein by reference.

What is claimed is:

1. A patterned substrate, comprising:
an element forming surface;
a plurality of patterns formed on the element forming surface by drying liquid droplets containing a pattern forming material, and
a photothermal conversion part configured to convert infrared light into heat provided on an outside perimeter of each of a plurality of pattern forming regions, each pattern forming region being formed to correspond to each of the patterns.

2. The patterned substrate recited in claim 1, wherein
the photothermal conversion parts contain an infrared absorbing pigment.

3. The patterned substrate recited in claim 1, wherein
each photothermal conversion part is provided with a partitioning wall configured to hold the liquid droplets in the respective pattern forming region.

4. The patterned substrate recited in claim 1, wherein
the pattern forming material is a light emitting element forming material and the patterns are light emitting elements.

5. The patterned substrate recited in claim 1, wherein
the pattern forming material is a color filter forming material; and
the patterns are color filters.

6. The patterned substrate recited in claim 5, wherein
each photothermal conversion part is a light blocking film that shields the outside perimeter of the respective color filter.

7. The patterned substrate recited in claim 1, wherein
the patterned substrate is a wiring forming material; and
the patterns are wiring patterns.

8. An electro-optical device comprising:
a plurality of light emitting elements formed by drying liquid droplets containing a light emitting element forming material, wherein
a photothermal conversion part configured to convert infrared light into heat provided on the outside perimeter of each of a plurality of light emitting element forming regions, each light emitting element forming region being formed to correspond to one of the light emitting elements.

9. The electro-optical device recited in claim 8, wherein
the photothermal conversion parts contain an infrared absorbing pigment.

10. The electro-optical device recited in claim 8, wherein
each photothermal conversion part is provided with a partitioning wall configured to hold the liquid droplets in the respective light emitting device forming region.

11. The electro-optical device recited in claim 8, wherein
each photothermal conversion part is a light blocking film that shields the outside perimeter of the respective light emitting element.

12. The electro-optical device recited in claim 8, wherein
each light emitting elements is an electroluminescent element having a light emitting layer between a transparent electrode and a rear electrode.

13. The electro-optical device recited in claim 12, wherein
the light emitting elements are organic electroluminescent elements in which the light emitting layer is made of an organic material.

14. A method of manufacturing a patterned substrate having a plurality of patterns formed by drying liquid droplets containing a pattern forming material, comprising
providing a photothermal conversion part that is configured to convert infrared light into heat on an outside perimeter of each of a plurality of pattern forming regions, each pattern forming region corresponding to each of the patterns;
forming the liquid droplets within the pattern forming regions; and
shining infrared light on the patterned forming regions; and
drying the liquid droplets by heat resulting from the photothermal conversion by the photothermal conversion parts.

15. The patterned substrate manufacturing method recited in claim 14, wherein
the liquid droplets are ejected by means of a liquid droplet ejection device.

16. The patterned substrate manufacturing method recited in claim 14, wherein
the infrared light is shone on the patterned forming regions after liquid droplets are formed in the pattern forming regions.

17. The patterned substrate manufacturing method recited in claim 14, wherein
the infrared light is shone on the photothermal conversion parts of the pattern forming regions while liquid droplets are formed in the pattern forming regions.
